(19) United States
(12) Patent Application Publication
(10) Pub. No.: US 2015/0017814 A1
(43) Pub. Date: Jan. 15, 2015

(54) METHOD OF FORMING GATE OXIDE LAYER

(71) Applicant: Shanghai Huali Microelectronics Corporation, Shanghai (CN)

(72) Inventors: Hongwei ZHANG, Shanghai (CN); Shu Koon PANG, Shanghai (CN)

(73) Assignee: Shanghai Huali Microelectronics Corporation, Shanghai (CN)

(21) Appl. No.: 14/084,012

(22) Filed: Nov. 19, 2013

(30) Foreign Application Priority Data
Jul. 9, 2013 (CN) 201310287391.5

(51) Int. Cl. H01L 21/28

(52) U.S. Cl. CPC H01L 21/28185; H01L 21/28202
USPC 438/766

(57) ABSTRACT

A method of forming a gate oxide layer is disclosed, which introduces a rapid laser annealing process, performed on the surface of the gate SiON layer, prior to a high-temperature annealing process performed on the gate SiON layer. This enables the method of the invention to remove the intrinsic oxide layer, protect the doped nitrogen atoms from the adverse influence of organic absorption, and lead to the formation of an amorphized surface layer which is able to prevent nitrogen atoms located around the surface from escaping by volatilization and nitrogen atoms beneath the surface from diffusing towards the SiO₂/Si boundary. Therefore, the gate SiON layer formed by the method of the invention can ensure a high and stable nitrogen content, thus achieving the objective to obtain a gate SiON layer with a more precisely trimmed dielectric constant and hence improve the electrical properties of the semiconductor device being fabricated.

### CROSS-REFERENCES TO RELATED APPLICATIONS

This application claims the priority of Chinese patent application number 201310287391.5, filed on Jul. 9, 2013, the entire contents of which are incorporated herein by reference.

### TECHNICAL FIELD

The present invention relates generally to the fabrication of semiconductor devices, and more particularly, to a method of forming gate oxide layer.

### BACKGROUND

Rapid development of Very Large-Scale Integration (VLSI) and Ultra Large-Scale Integration (ULSI) has brought significant challenges to many techniques involved in the fabrication of semiconductor devices. For example, with the critical dimension of Metal Oxide Semiconductor (MOS) devices scaling down to the nanometer realm, the semiconductor devices are required to have a gate oxide layer with a better performance. The process for forming a gate oxide layer is an essential process in semiconductor device fabrication, because it relates to and even determines the electrical characteristics and reliability of the semiconductor device being fabricated.

The most important factor for the performance of a Metal-Oxide-Semiconductor Field-Effect Transistor (MOSFET) is its drive current. The magnitude of the drive current is determined by the capacitance of a gate of the device. As the capacitance of the gate is proportional to a surface area of the gate while inversely proportional to a thickness of a gate dielectric, it can be improved either by increasing the surface area of the gate or by reducing the thickness of the gate dielectric. Therefore, promoting the performance of MOSFET devices by means of thinning the gate dielectric was predominant in this field.

However, with the semiconductor manufacturing technology moving into the 45 nm technology node, the conventional techniques previously used to reduce SiO₂ gate dielectric thickness faced an unprecedented challenge. This is because most existing semiconductor devices have already included a rather thin SiO₂ :gate dielectric (typically with a thickness smaller than 20 Å), resulting in the tunneling mechanism dominating the gate leakage current, and further reduction of the dielectric thickness will cause an exponential rise in the gate leakage current. Impractically, every decrease of 2 Å in the gate dielectric thickness will lead to a 10-times increase of the gate leakage current. On the other hand, in general, there are dopant concentration gradients between the gate and the SiO₂ gate dielectric and between the SiO₂ gate dielectric and a semiconductor substrate of the MOSFET device. Further decrease of the dielectric thickness will cause boron or other dopants in the gate to diffuse into the semiconductor substrate or persistently stay in the gate dielectric, thus adversely affecting a threshold voltage and hence the performance of the MOSFET device. While it is a matter of course that any increase in the gate dielectric thickness will effectively suppress the gate leakage current and the diffusion of gate dopants, it is disadvantageous that such increase will also lead to deterioration of key characteristics of the MOSFET device such as the drive current and switching delay. These conflicting requirements on the gate dielectric thickness respectively from the drive current and the gate leakage current were unavoidable for conventional semiconductor devices including a SiO₂ gate dielectric.

By further referring to the calculation expression of the gate capacitance, C=e₀KA/t, where, C represents the gate capacitance, e₀ represents the permittivity of free space, K represents the dielectric constant of the gate dielectric, A represents the surface area of the gate, and t represents the thickness of the gate dielectric, we can find, in addition to the gate surface area and the gate dielectric thickness, the gate capacitance is also determined by the dielectric constant K of the gate dielectric. Therefore, physically reducing the gate dielectric thickness is not the only way to improve the gate capacitance, instead, improving the dielectric constant K can provide an alternative way to result in an equivalent reduction in the thickness of the oxide dielectric (i.e., an equivalent oxide thickness (EOT) reduction) and improvement of the gate capacitance, even when the physical gate dielectric thickness is kept unchanged. For this reason, current research in this field is directed towards the improvement of the dielectric constant K of the gate dielectric.

As of today, there have been several methods developed in order to improve the dielectric constant K, which can be classified overall into the following two categories.

Methods of the first category use hafnium silicon oxynitride (HfSiON) or other high dielectric constant materials to form the gate dielectric. However, the utilization of the totally new gate dielectric material requires further adoption of a new gate material whose lattice constant should be compatible with that of the new gate dielectric material, as well as corresponding adjustments in conditions of exposure, etching and other processes, in order to integrate the new gate dielectric material into the existing fabrication processes. This leads to a long technology development cycle and makes the method unable to satisfy the urgent needs of the 45 nm technology node in a timely way. Further, the technological updates accompanying the utilization of the new gate dielectric material are expensive.

Methods of the second category choose to nitridate the SiO₂ gate dielectric into compact silicon oxynitride (SiON) that has a higher dielectric constant. Compared to the dielectric constant of conventional SiO₂ gate dielectric that is 3.9, the K value of pure silicon nitride (Si₃N₄) is up to 7. These methods have advantages as follows: 1) they can result in SiON gate dielectric with a desired dielectric constant by doping the SiO₂ gate dielectric with an appropriate quantity of nitrogen; 2) doped nitrogen atoms can effectively inhibit boron and other dopant from diffusing from the gate into the substrate; and 3) as SiO₂ still serves as a main basis of the gate dielectric, the methods are consistent and compatible with existing fabrication processes.

Currently, manufacturers can choose three major methods to obtain SiON by doping SiO₂ with nitrogen.

The first method is to introduce nitrogen monoxide (NO) or another nitrogen-containing gas during the growth of SiO₂. However, due to a typical non-uniform distribution of nitrogen atoms in the doped SiO₂, this method is poorly suitable for semiconductor device fabrication.

The second method is to anneal grown SiO₂ dielectric in an atmosphere of NO/nitrous oxide (N₂O) or another nitrogen-containing gas. However, nitrogen atoms doped by this method are prone to gather around the boundary between the SiO₂ gate dielectric, and a conductive channel and thus adversely affect the drift velocity of carriers in the channel.

The third method is to dope the SiO₂ gate dielectric with nitrogen plasma. As this method is capable of achieving a high concentration of nitrogen atoms distributed in proximity of an upper surface of the gate dielectric rather than around the SiO₂/channel boundary, it is widely accepted by the manufacturers as an effective approach to improve the gate dielectric constant.

Nevertheless, the nitrogen atoms present in a high concentration around the upper surface of the gate dielectric requires a subsequent high-temperature post nitridation anneal (PNA) process to be performed in a strictly controlled time interval so as to prevent the doped nitrogen atoms from being affected by the intrinsic oxide layer and organic absorption. In addition, the high-temperature PNA process can easily cause nitrogen atoms around the surface of the gate dielectric to escape by volatilization and nitrogen atoms in the gate dielectric to gain energy for further diffusion downwards which may lead to nitrogen atoms gathering around the SiO₂/Si boundary and thus affecting the channel carrier velocity.

### SUMMARY OF THE INVENTION

It is therefore an objective of the invention to provide a method of forming a gate oxide layer to address the above described issues of the prior art methods, i.e., the great difficulty in controlling the gate oxide formation process and high risk in causing nitrogen atoms to escape by volatilization or gain energy for further diffusion downwards which may lead to nitrogen atoms gathering around the SiO₂/channel boundary and thus affecting channel carrier velocity.

The foregoing objective is attained by a method of forming a gate oxide layer, including the following steps in the sequence set forth:

providing a silicon substrate and performing a thermal oxidation process and other thermal processes to form a gate silicon dioxide layer on a surface of the silicon substrate;

implanting nitrogen in the gate silicon dioxide layer using a plasma nitridation process to form a gate silicon oxynitride layer;

performing a rapid laser annealing process on a surface of the gate silicon oxynitride layer; and

performing a high-temperature thermal annealing process to the gate silicon oxynitride layer.

Optionally, the thermal oxidation may include one of a rapid thermal process and a vertical furnace process.

Optionally, the rapid thermal process may include one of an in-suit steam generation (ISSG) process and a rapid thermal oxidation process.

Optionally, the ISSG process may be a nitrous oxide in-suit steam generation process using nitrous oxide and hydrogen as reactant gases, or a hydrogen in-suit steam generation process using oxygen and hydrogen as reactant gases.

Optionally, the plasma nitridation process may be a decoupled plasma nitridation process, a remote plasma nitridation process, or a nitridation process using a nitrogen source of a vertical diffusion apparatus.

Optionally, the nitrogen source of the vertical diffusion apparatus may include one selected from the group consisting of nitrogen monoxide, nitrous oxide and ammonia.

Optionally, the rapid laser annealing process may be a laser spike anneal process using a laser with a wavelength of 10.6 μm, a flash lamp anneal process using a laser with a wavelength of 0.5 μm to 0.8 μm, or a diode laser anneal process using a laser with a wavelength of 0.8 μm.

Optionally, the rapid laser annealing process may be performed at a temperature of 1100° C. to 1400° C.

Optionally, the high-temperature thermal annealing process may include a rapid thermal process or a vertical furnace process.

Optionally, the high-temperature thermal annealing process may be performed at a temperature of 1000° C. to 1100° C.

Optionally, the rapid thermal process may be a one-step high-temperature annealing process performed in an atmosphere of nitrogen, oxygen, or nitrous oxide, or a two-step process consisting of a first high-temperature annealing process performed in an atmosphere of nitrogen or a mixture gas of oxygen and nitrogen and a second high-temperature annealing process performed in an atmosphere of oxygen or a mixture gas of oxygen and nitrogen.

Optionally, the vertical furnace process may include a high-temperature process performed in an atmosphere of nitrogen, helium, or argon.

As noted above, the method of the present invention advantageously employs, prior to the high-temperature annealing process performed on the gate SiON layer, the rapid laser annealing process performed on the surface of the SiON layer to remove the intrinsic oxide layer and protect the doped nitrogen atoms from the adverse influence of organic absorption. Also advantageously, the rapid laser annealing process leads to the formation of an amorphized surface layer which is capable of preventing nitrogen atoms located around the surface from escaping by volatilization and nitrogen atoms beneath the surface from diffusing towards the SiO₂/Si boundary. Still also advantageously, the gate SiON layer formed by the method of the present invention can ensure a high and stable nitrogen content, thus achieving the objective to obtain a gate SiON layer with a more precisely trimmed dielectric constant and hence improve the electrical properties of the semiconductor device being fabricated.

### BRIEF DESCRIPTION OF THE DRAWINGS

FIG. 1 depicts a flow chart graphically illustrating a method of forming a gate oxide layer in accordance with an embodiment of the present invention.

### DETAILED DESCRIPTION

The present invention is suited to gate oxide layer formation at 45 nm technology nodes or beyond of the complementary metal-oxide-semiconductor (CMOS) technology. Technical details, features, objects, and advantages of the present invention will be fully understood in view of the following detailed description, in conjunction with the accompanying drawing.

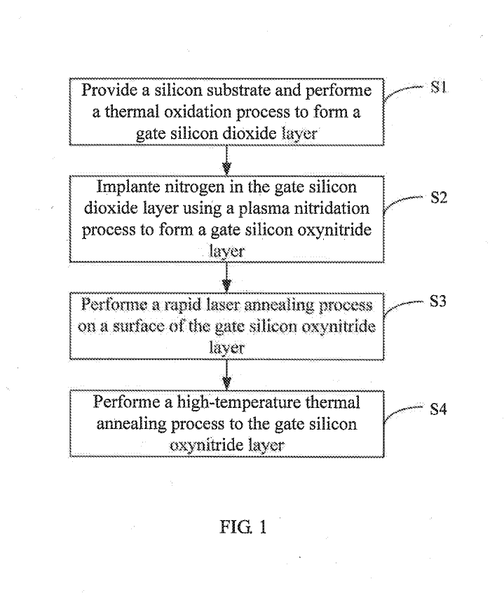

FIG. 1 is a flow chart graphically depicting a method of forming a gate oxide layer in accordance with an embodiment of the present invention. The method includes the steps of:

step S1, providing a silicon substrate and performing a thermal oxidation process to form a gate silicon dioxide layer on a surface of the silicon substrate;

step S2, implanting nitrogen in the gate silicon dioxide layer using a plasma nitridation process to form a gate silicon oxynitride layer;

step S3, performing a rapid laser annealing process on a surface of the gate oxynitride layer; and

step S4, performing a high-temperature thermal annealing process to the gate oxynitride layer.

In the step S1, the thermal oxidation process may include, but not limited to, one of a rapid thermal process and a vertical furnace process. Additionally, the rapid thermal process may include, but not limited to, one of an in-suit steam generation (ISSG) process and a rapid thermal oxidation (RTO) process. Further, one of ordinary skill in the art will easily understand that the ISSG process may be, but not limited to, a nitrous oxide (N₂O) ISSG process using N₂O and molecular hydrogen (H₂) as the reactant gases, or a H₂ ISSG process using molecular oxygen (O₂) and H₂ as the reactant gases.

In the step S2, the plasma nitridation process may be, but not limited to, a decoupled plasma nitridation (DPN) process, a remote plasma nitridation (RPN) process, or a nitridation process using a nitrogen source of a vertical diffusion apparatus. Further, the nitrogen source of the vertical diffusion apparatus may include, but not limited to, one selected from the group consisting of nitrogen monoxide (NO), N₂O and ammonia (NH3).

In the step S3, the rapid laser annealing process may be, but not limited to, a laser spike anneal (LSA) process using a laser with a wavelength of 10.6 μm, a flash lamp anneal (FLA) process using a laser with a wavelength of 0.5 μm to 0.8 μm, or a diode laser anneal (DLA) process using a laser with a wavelength of 0.8 μm. Further, the rapid laser annealing process may be performed at a temperature T1 of 1100° C. to 1400° C.

In the step S4, the high-temperature thermal annealing process may include, but not limited to, a rapid thermal process or a vertical furnace process. Additionally, the high-temperature thermal annealing process may be performed at a temperature T2 of 1000° C. to 1100° C. Moreover, the rapid thermal process may be, but not limited to, a one-step high-temperature annealing process performed in an atmosphere of N₂, O₂, or N,O, or a two-step process consisting of a first high-temperature annealing process performed in an atmosphere of molecular nitrogen (N₂) or a mixture of O₂ and N₂ and a second high-temperature annealing process performed in an atmosphere of O₂ or a mixture of O₂ and N₂. Further, the vertical furnace process may include, but not limited to, a high-temperature process performed in an atmosphere of a N₂, helium (He), or argon (Ar).

Obviously, the introduction of the rapid laser annealing process performed on the surface of the gate SiON layer, prior to the high-temperature annealing process performed on the gate SiON layer to repair lattice damage and the SiO₂/Si interlayer boundary, enables the method of the present invention to remove the intrinsic oxide layer and protect doped nitrogen atoms from the adverse influence of organic absorption. Meanwhile, because the rapid laser annealing process is performed at a high temperature (e.g., between 1100° C. and 1400 ° C.) for a period of time (typically longer than or equal to 200 μsec) too short to cause further dopant diffusion, the rapid laser annealing process leads to the formation of an amorphized surface layer which is capable of preventing nitrogen atoms located around the surface from escaping by volatilization and nitrogen atoms beneath the surface from diffusing towards the SiO₂/Si boundary, thus reducing, to a highest possible extent, the gathering of nitrogen atoms around the SiO₂/Si boundary and improving the drift velocity of channel carriers. Moreover, the gate SiON layer formed by the method of the present invention can ensure a high and stable nitrogen content, thus achieving the purpose to obtain a gate SiON layer with a more precisely trimmed dielectric constant and hence improve the electrical properties of the semiconductor device being fabricated.

Those skilled in the art will appreciate that various modifications and variations can be made to the present invention without departing from the scope of the invention. Accordingly, it is intended that the present invention embraces all such modifications and variations as fall within the scope of the appended claims and equivalents thereof.

What is claimed is:

1. A method of forming gate oxide layer, comprising the following steps in the sequence set forth:
providing a silicon substrate and performing a thermal oxidation process to form a gate silicon dioxide layer on a surface of the silicon substrate;
implanting nitrogen in the gate silicon dioxide layer using a plasma nitridation process to form a gate silicon oxynitride layer;
performing a rapid laser annealing process on a surface of the gate silicon oxynitride layer; and
performing a high-temperature thermal annealing process to the gate silicon oxynitride layer.

2. The method of claim 1, wherein the thermal oxidation process includes one of a rapid thermal process and a vertical furnace process.

3. The method of claim 2, wherein the rapid thermal process includes one of an in-suit steam generation process and a rapid thermal oxidation process.

4. The method of claim 3, wherein the in-suit steam generation process is a nitrous oxide in-suit steam generation process using nitrous oxide and hydrogen as reactant gases, or a hydrogen in-suit steam generation process using oxygen and hydrogen as reactant gases.

5. The method of claim 1, wherein the plasma nitridation process is a decoupled plasma nitridation process, a remote plasma nitridation process, or a nitridation process using a nitrogen source of a vertical diffusion apparatus.

6. The method of claim 5, wherein the nitrogen source of the vertical diffusion apparatus includes one selected from the group consisting of nitrogen monoxide, nitrous oxide and ammonia.

7. The method of claim 1, wherein the rapid laser annealing process is a laser spike anneal process using a laser with a wavelength of 10.6 μm, a flash lamp anneal process using a laser with a wavelength of 0.5 μm to 0.8 μm, or a diode laser anneal process using a laser with a wavelength of 0.8 μm.

8. The method of claim 7, wherein the rapid laser annealing process is performed at a temperature of 1100° C. to 1400° C.

9. The method of claim 1, wherein the high-temperature thermal annealing process includes one of a rapid thermal process and a vertical furnace process.

10. The method of claim 9, wherein the high-temperature thermal annealing process is performed at a temperature of 1000° C. to 1100° C.

11. The method of claim 10, wherein the rapid thermal process is a one-step high-temperature annealing process performed in an atmosphere of nitrogen, oxygen, or nitrous oxide, or a two-step process consisting of a first high-temperature annealing process performed in an atmosphere of nitrogen or a mixture gas of oxygen and nitrogen and a second high-temperature annealing process performed in an atmosphere of oxygen or a mixture gas of oxygen and nitrogen.

12. The method of claim 10, wherein the vertical furnace process includes a high-temperature process performed in an atmosphere of nitrogen, helium, or argon.
